(19) United States
(12) Patent Application Publication
(10) Pub. No.: US 2010/0252885 A1
(43) Pub. Date: Oct. 7, 2010

(54) SEMICONDUCTOR DEVICE AND DISPLAY DEVICE

(75) Inventors: Yasumori Fukushima, Osaka-shi (JP); Yutaka Takafuji, Osaka-shi (JP); Kenshi Tada, Osaka-shi (JP)

Correspondence Address: SHARP KABUSHIKI KAISHA;C/O KEATING & BENNETT, LLP, 1800 Alexander Bell Drive, SUITE 200, Reston, VA, 20191, US

(73) Assignee: SHARP KABUSHIKI KAISHA, Osaka-shi, Osaka (JP)

(21) Appl. No.: 12/742,463

(22) PCT Filed: Sep. 19, 2008
(86) PCT No.: PCT/JP2008/067013

§ 371 Date: May 12, 2010

(30) Foreign Application Priority Data
Jan. 21, 2008 (JP) 2008-010942

(51) Int. Cl. H01L 27/12

(52) U.S. Cl. 257/348; 257/E27.112

(57) ABSTRACT

A semiconductor device (10) is formed by bonding a semiconductor substrate (1) including a CMOS transistor (3) to a glass substrate (2). The semiconductor substrate (1) is formed by partial separation at a separation layer. A P-type high concentration impurity region (39n) is formed in electric connection with a channel region (35n) of an NMOS transistor (3n) so that an electric potential of the channel region (35n) is fixed. The P-type high concentration impurity region (39n) has the same P conductive type as that of the channel region (35n) and also has a concentration higher than that of the channel region (35n). An N-type high concentration impurity region (39p) is formed in electric connection with a channel region (35p) of a PMOS transistor (3p) so that an electric potential of the channel region (35p) is fixed. The N-type high concentration impurity region (39p) has the same N conductive type as that of the channel region (35p) and also has a concentration higher than that of the channel region (35p). This makes it possible to provide a semiconductor device whose performance can be enhanced by restraint on variation in a characteristic of a thin film transistor and a display device including the semiconductor device.

### TECHNICAL FIELD

The present invention relates to a semiconductor device in which a thin film transistor (TFT) used for, for example, an active-matrix-drive display device is formed on a glass substrate.

### BACKGROUND ART

A so-called active-matrix-drive liquid crystal display device has been conventionally used. Such an active-matrix-drive liquid crystal display device is obtained by forming a thin film transistor made of amorphous silicon or polycrystalline silicon on a glass substrate, and drives a liquid crystal display panel or the like.

The active-matrix-drive liquid crystal display device employs, particularly, a silicon device (semiconductor device) in which peripheral drivers are integrated by use of polycrystalline silicone that has a high mobility and that operates at a high speed. However, in the polycrystalline silicon, a mobility decreases and/or a coefficient S (subthreshold coefficient) increases, due to a localized level caused within a gap by an imperfect crystallinity, a defect in the vicinity of a crystal grain boundary, and/or a localized level within a gap. Therefore, the thin film transistor using the polycrystalline silicon is not always sufficient in performance. Particularly, for integrating systems such as an image processor, a timing controller, a CPU, a memory and a power supply circuit which are each required to have a higher performance, a higher-performance semiconductor device is essential. However, the thin film transistor made of polycrystalline silicon is not capable of satisfying the requirement.

Therefore, a technique is proposed for forming a higher-performance semiconductor device. In the technique, a device such as a thin film transistor made of single-crystal silicon thin film is preformed on a semiconductor substrate, and the device is then attached onto an insulating substrate such as a glass substrate.

As an example of the technique, for example, Patent Literature 1 discloses a technique in which a preformed single-crystal silicon thin film transistor is transferred onto a glass substrate using an adhesive.

However, the semiconductor device and a manufacturing method thereof in Patent Literature 1 require an adhesive. Therefore, it takes time to attach the transistor onto the substrate, which causes a problem such as a low productivity. Further, a joint section is bonded by an adhesive. Therefore, a complete semiconductor device is also inferior in heat resistance, which has an adverse effect on an operation performance.

Therefore, as a method for solving the problems, for example, Patent Literature 2 discloses the following technique. In a semiconductor device of Patent Literature 2, an oxide film, a gate pattern and an impurity ion implantation section, each of which forms a part of a MOS single-crystal silicon thin film transistor, are formed on a surface of a single-crystal silicon substrate to be bonded to an insulating substrate such as a glass substrate, and a hydrogen ion implantation section (separation layer) at a predetermined concentration is provided at a predetermined depth in the single-crystal silicon substrate.

According to the configuration, the single-crystal silicon substrate is bonded to the insulating substrate so that a side where the oxide film is formed on the single-silicon substrate is bonded to the insulating substrate. Thereafter, a heat treatment is performed so that the substrates are securely bonded to each other due to bonding between atoms. The heat treatment also can cause separation at the separation layer. Thus, the MOS single-crystal silicon thin film transistor can be easily obtained.

Patent Literature 1

Japanese Patent Application Publication, Tokuhyohei, No. 7-503557 A (Publication Date: Apr. 13, 1995)

Patent Literature 2

Japanese Patent Application Publication, Tokukai, No. 2004-165600 A (Publication Date: Jun. 10, 2004)

### SUMMARY OF INVENTION

However, the conventional technique causes deterioration in a characteristic of a transistor. Specifically, the thin film transistor is operated by application of voltage to three terminals of a gate, a source and a drain. Therefore, an electric potential in a channel region falls into a floating state. Accordingly, the electric potential is likely to be influenced by a surrounding electric field. This causes, particularly in a transistor that has a short gate, a phenomenon (DIBL: Drain Induced Barrier Lowering) in which, as a drain voltage increases, an electric potential in the vicinity of the source declines due to a drain electric field. This noticeably causes a short channel phenomenon in which a threshold of the transistor changes. Thus, in the thin film transistor, because the electric potential in the channel region is not fixed, a change in the drain voltage varies the electric potential in the channel region. This in turn varies the threshold of the transistor.

Further, in the conventional technique, a separation plane (boundary surface) is formed by separation at the hydrogen ion implantation section (separation layer). The separation plane becomes uneven and poor in flatness. This also varies a characteristic of a transistor. It is known that a threshold voltage which is an indicator of a characteristic of a transistor varies not only due to an influence of variation in the foregoing substrate electric potential but also due to a thickness of a thin film silicon layer. Therefore, when a boundary surface thereof becomes uneven in a case where a part of a single-crystal silicon substrate is separated so that a thin film transistor is formed according to a conventional technique, a thickness of a silicon thin film becomes uneven. As a result, the threshold voltage of the transistor varies. For restraining such a variation in a thickness of a silicon thin film, it may be considered to make the boundary surface flat, for example, by grinding. However, such a method has a technical problem in that it is difficult to handle a large substrate by such a method. Accordingly, it is very difficult to control the flatness of the boundary surface at a high accuracy.

Thus, the conventional technique has a problem of deterioration in a characteristic of a transistor, for example, variation in a threshold voltage of the transistor.

The present invention is made in view of the problems described above, and an object of the present invention is to achieve a semiconductor device whose performance can be enhanced by restraining variation in a characteristic of a thin film transistor, and a display device including the semiconductor device.

A semiconductor device of the present invention, in order to solve the problems, is formed by bonding a first substrate and a second substrate. The first substrate includes a field-effect transistor and is formed by partial separation at a separation layer. In the semiconductor device of the present invention, a high concentration impurity region is formed in electric connection with a channel region of the field-effect transistor of the first substrate so that an electric potential of the channel region is fixed. The high concentration impurity region has the same conductive type as that of the channel region and also has a concentration higher than that of the channel region.

The semiconductor device of the present invention is formed as described above by bonding the first substrate including the field-effect transistor (for example, a CMOS transistor) to the second substrate such as a glass substrate. The first substrate is formed by partial separation at the separation layer.

In the semiconductor device, with the above structure, for example, a P-type high concentration impurity region is formed in electric connection with a channel region of an NMOS transistor constituting, for example, a CMOS transistor so that an electric potential of the channel region is fixed. The P-type high concentration impurity region has the same conductive type (P-type) as that of the channel region and also has a concentration higher than that of the channel region. Further, in a PMOS transistor, an N-type high concentration impurity region is formed in electric connection with a channel region of the PMOS transistor so that an electric potential of the channel region is fixed. The N-type high concentration impurity region has the same conductive type (N-type) as that of the channel region and also has a concentration higher than that of the channel region. Note that the channel region indicates a semiconductor region including a channel formed below a gate.

This makes it possible to fix the electric potential of the channel region that has been in a floating state. Accordingly, the variation in the threshold of the transistor can be restrained. More specifically, for example, in the NMOS transistor, the N-type high concentration impurity region which has the same conductive type as the channel region is electrically connected to a source electrode. This electrically connects the channel region to a source region via the N-type high concentration impurity region. Accordingly, the electric potential of the channel region becomes the same as an electric potential of the source region. Therefore, the electric potential of the channel region is not varied by a change of a drain voltage or the like, but is fixed. Consequently, the variation in the threshold of the transistor is restrained.

In this way, because the variation in the threshold of the transistor is restrained, variation in the characteristic of the transistor can be restrained. This makes it possible to enhance performance of the semiconductor device.

It is preferable to arrange the semiconductor device of the present invention such that, in the semiconductor device, the high concentration impurity region is formed in a source region of the field-effect transistor.

With the structure, because the high concentration impurity region is formed in the source region, the channel region can be easily electrically connected to the source region via the high concentration impurity region. This makes it possible to fix the electric potential of the channel region to the same electric potential as that of the source region.

It is preferable to arrange the semiconductor device of the present invention such that, in the semiconductor device, the high concentration impurity region is formed so as to be adjacent to the channel region in the source region.

This makes it possible to electrically connect the channel region to the source region more easily.

It is preferable to arrange the semiconductor device of the present invention such that, in the semiconductor device, the high concentration impurity region is formed so as not to be adjacent to the channel region in the source region.

Even if the high concentration impurity region is formed not to be adjacent to the channel region in the source region, the channel region can be electrically connected to the source region. Accordingly, flexibility in designing can be improved.

It is preferable to arrange the semiconductor device of the present invention such that, in the semiconductor device, a film thickness of a silicon layer formed in the channel region in the field-effect transistor is greater than a maximum depletion layer width in the channel region.

With the above structure, when a gate voltage is applied and a channel is formed, there is still a layer which is present directly below the channel and which has the same conductive type as that of the high concentration impurity region. Therefore, an electric potential of the channel can be more reliably fixed over the whole channel region.

It is preferable to arrange the semiconductor device of the present invention such that, in the semiconductor device, the field-effect transistor includes at least one of an NMOS transistor and a PMOS transistor.

It is preferable to arrange the semiconductor device of the present invention such that, in the semiconductor device, the first substrate includes single-crystal silicon semiconductor, or at least one selected from a group including Group IV semiconductor, Group II-VI compound semiconductor, Group III-V compound semiconductor, Group IV-IV compound semiconductor, mixed crystal semiconductor containing congeners of one of Group IV, Groups II-VI, Groups III-V, and Groups IV-IV, and an oxide semiconductor.

It is preferable to arrange the semiconductor device of the present invention such that, in the semiconductor device, the high concentration impurity region and the source region are electrically connected to a source electrode. This makes it possible to fix the electric potential of the channel region to the same potential as that of the source region.

It is preferable to arrange the semiconductor device of the present invention such that, in the semiconductor device, the high concentration impurity region is connected to ground.

This makes it possible to fix the electric potential of the channel region to a ground level.

It is preferable to arrange the semiconductor device of the present invention such that, in the semiconductor device, the second substrate is a glass substrate.

A display device of the present invention includes any one of the semiconductor devices described above.

This makes it possible to provide a display device whose performance can be enhanced by restraint on variation in a characteristic of a thin film transistor.

For a fuller understanding of the nature and advantages of the invention, reference should be made to the ensuing detailed description taken in conjunction with the accompanying drawings.

### BRIEF DESCRIPTION OF DRAWINGS

FIG. 1

FIG. 1 is a cross-sectional view showing an embodiment of a semiconductor device of the present invention.

FIG. 2

FIG. 2 is a plain view schematically showing another structure of an NMOS transistor in the semiconductor device shown in FIG. 1.

FIG. 3

FIG. 3 is a cross-sectional view illustrating a step of forming a thermal oxide film (2) in a production process of the semiconductor device shown in FIG. 1.

FIG. 4

FIG. 4 is a cross-sectional view illustrating a step of injecting an N-type impurity element (4) in the production process of the semiconductor device shown in FIG. 1.

FIG. 5

FIG. 5 is a cross-sectional view illustrating a step of injecting a P-type impurity element (5) in the production process of the semiconductor device shown in FIG. 1.

FIG. 6

FIG. 6 is a cross-sectional view illustrating a step of forming an N-well region (7) and a P-well region (8) in the production process of the semiconductor device shown in FIG. 1.

FIG. 7

FIG. 7 is a cross-sectional view illustrating a step of patterning a silicon nitride film (9) and a thermal oxide film (6) in the production process of the semiconductor device shown in FIG. 1.

FIG. 8

FIG. 8 is a cross-sectional view illustrating a step of forming a LOCOS oxide film (10) in the production process of the semiconductor device shown in FIG. 1.

FIG. 9

FIG. 9 is a cross-sectional view illustrating a step of forming an oxide film (11) in the production process of the semiconductor device shown in FIG. 1.

FIG. 10

FIG. 10 is a cross-sectional view illustrating a step of forming a resist (12) in the production process of the semiconductor device shown in FIG. 1.

FIG. 11

FIG. 11 is a cross-sectional view illustrating a step of forming a resist (14) in the production process of the semiconductor device shown in FIG. 1.

FIG. 12

FIG. 12 is a cross-sectional view illustrating a step of forming a gate oxide film (16) in the production process of the semiconductor device shown in FIG. 1.

FIG. 13

FIG. 13 is a cross-sectional view illustrating a step of forming gate electrodes (17) in the production process of the semiconductor device shown in FIG. 1.

FIG. 14

FIG. 14 is a cross-sectional view illustrating a step of forming an N-type low concentration impurity region (20) in the production process of the semiconductor device shown in FIG. 1.

FIG. 15

FIG. 15 is a cross-sectional view illustrating a step of forming a P-type low concentration impurity region (23) in the production process of the semiconductor device shown in FIG. 1.

FIG. 16

FIG. 16 is a cross-sectional view illustrating a step of forming SiO₂ sidewalls (24) in the production process of the semiconductor device shown in FIG. 1.

FIG. 17

FIG. 17 is a cross-sectional view illustrating a step of forming an N-type high concentration impurity region (27p) in the production process of the semiconductor device shown in FIG. 1.

FIG. 18

FIG. 18 is a cross-sectional view illustrating a step of forming a P-type high concentration impurity region (30n) in the production process of the semiconductor device shown in FIG. 1.

FIG. 19

FIG. 19 is a cross-sectional view illustrating a step of forming a planarizing film (31) in the production process of the semiconductor device shown in FIG. 1.

FIG. 20

FIG. 20 is a cross-sectional view illustrating a step of forming a separation layer (33) in the production process of the semiconductor device shown in FIG. 1.

FIG. 21

FIG. 21 is a cross-sectional view illustrating a step of forming metal electrodes (36) in the production process of the semiconductor device shown in FIG. 1.

FIG. 22

FIG. 22 is a cross-sectional view illustrating a step of bonding a glass substrate (38) in the production process of the semiconductor device shown in FIG. 1.

FIG. 23

FIG. 23 is a cross-sectional view illustrating a separation step in the production process of the semiconductor device shown in FIG. 1.

FIG. 24

FIG. 24 is a cross-sectional view illustrating a step of forming a protective film (39) in the production process of the semiconductor device shown in FIG. 1.

FIG. 25

FIG. 25 is a cross-sectional view illustrating a step of forming metal wirings (41) in the production process of the semiconductor device shown in FIG. 1.

FIG. 26

FIG. 26 is a plain view showing an embodiment of a semiconductor device of the present invention.

### REFERENCE SIGNS LIST

1: SEMICONDUCTOR SUBSTRATE (FIRST SUBSTRATE)
2: GLASS SUBSTRATE (SECOND SUBSTRATE)
3: CMOS TRANSISTOR
3n: NMOS TRANSISTOR
3p: PMOS TRANSISTOR
4: LOCOS OXIDE FILM
5: PROTECTIVE FILM
10: SEMICONDUCTOR DEVICE
30n and 30p: SOURCE REGION
31n and 31p: GATE ELECTRODE
32n and 32p: SOURCE ELECTRODE
33n and 33p: DRAIN ELECTRODE
34n and 34p: GATE OXIDE FILM
35n and 35p: CHANNEL REGION
36n and 36p: CONTACT HOLE
37n and 38n: N-TYPE HIGH CONCENTRATION IMPURITY REGION
37p and 38p: P-TYPE HIGH CONCENTRATION IMPURITY REGION
39n: P-TYPE HIGH CONCENTRATION IMPURITY REGION
39n: N-TYPE HIGH CONCENTRATION IMPURITY REGION
33: SEPARATION LAYER

### DESCRIPTION OF EMBODIMENTS

The following describes an embodiment of the present invention with reference to FIGS. 1 to 26.

A semiconductor device of the present invention is obtained by forming a MOS thin film transistor (TFT) on an insulating substrate, and is used for, for example, a display panel constituting an active-matrix-drive display device.

The MOS thin film transistor (MOS transistor) is a typical transistor (i) which includes a semiconductor layer, a gate electrode, a gate oxide film, high concentration impurity regions formed on both sides of a gate, and the like, and (ii) in which the gate electrode modulates a carrier concentration of the semiconductor layer below the gate so as to control an electric current flowing between a source and a drain. Examples of the MOS transistor include an N channel-type MOS transistor, a P channel-type MOS transistor and a CMOS transistor combining the N channel-type MOS transistor and the P channel-type MOS transistor. The CMOS transistor has a low power consumption and operates at a low voltage. Such a CMOS transistor is in heavy usage.

The present embodiment describes, as an example, a structure of the CMOS transistor. FIG. 1 is a cross-sectional view showing a structure of a semiconductor device 10 including a CMOS transistor 3.

The semiconductor device 10 includes a semiconductor substrate (first substrate) 1 and a glass substrate (second substrate) 2 as an insulating substrate which are attached to each other.

The semiconductor substrate 1 can be produced using a conventionally well-known technique, and includes the CMOS transistor 3. The CMOS transistor 3 includes an N channel-type MOS transistor (hereinafter referred to as an NMOS transistor 3n) and a P channel-type MOS transistor (hereinafter referred to as a PMOS transistor 3p) which are separated from each other by a LOCOS oxide film 4 formed therebetween. A method for producing the semiconductor substrate 1 is described later.

Note that the semiconductor substrate 1 contains single-crystal silicon semiconductor, or at least one selected from a group including Group IV semiconductor, Group II-VI compound semiconductor, Group III-V compound semiconductor, Group IV-IV compound semiconductor, mixed crystal semiconductor containing congeners of one of Group IV, Groups II-VI, Groups III-V and Groups IV-IV, and oxide semiconductor.

The glass substrate 2 is a non-alkali glass substrate that has a general optical transmittance (an amorphous-glass high strain point).

In each of the NMOS transistor 3n and the PMOS transistor 3p of the present embodiment, a high concentration impurity region is formed in electric connection with a channel region so that an electric potential of the channel region is fixed. The high concentration impurity region has the same conductive type as that of the channel region and also has a concentration higher than that of the channel region. The following concretely describes the structure with reference to FIG. 1.

The NMOS transistor 3n includes a gate electrode 31n, a source electrode 32n and a drain electrode 33n. On a side opposite to the gate electrode 31n, that is, on an opposite side of a gate oxide film 34n to a side where the gate electrode 31n is formed, a channel region 35n that is a P-type low concentration impurity region is formed. The source electrode 32n is electrically connected to an N-type high concentration impurity region 37n via a contact hole 36n. The drain electrode 33n is electrically connected to an N-type high concentration impurity region 38n via a contact hole 36n.

Further, in the NMOS transistor 3n of the present embodiment, a high concentration impurity region which has the same conductive type (here, P-type) as that of the channel region 35n and which also has a concentration higher than that of the channel region 35n, that is, a P-type high concentration impurity region 39n, is formed in electric connection with the channel region 35n. Furthermore, in the structure shown in FIG. 1, the P-type high concentration impurity region 39n is formed so as to be adjacent to the N-type high concentration impurity region 37n in a source region 30n, and is electrically connected to the source electrode 32n via the contact hole 36n.

It should be noted that a protective film 5 is formed on a surface of the semiconductor device 10 so as to ensure an electric insulation.

In a conventional semiconductor device, because a channel region is in a floating state in which an electric potential is not fixed, a threshold voltage of a transistor varies.

However, with the structure shown in FIG. 1, the channel region 35n is electrically connected to the source region 30n via the P-type high concentration impurity region 39n. Therefore, an electric potential of the channel region 35n is the same as that of the source region 30n. Accordingly, the electric potential of the channel region 35n is not varied by a change in a drain voltage, but is fixed. This makes it possible to restrain the variation in the threshold of the transistor.

The PMOS transistor 3p, as with the structure of the NMOS transistor, includes a gate electrode 31p, a source electrode 32p and a drain electrode 33p. On a side opposite to the gate electrode 31p, that is, on an opposite side of a gate oxide film 34p to a side where the gate electrode 31p is formed, a channel region 35p that is an N-type low concentration impurity region is formed. The source electrode 32p is electrically connected to a P-type high concentration impurity region 3′7p via a contact hole 36p. The drain electrode 33p is electrically connected to a P-type high concentration impurity region 38p via a contact hole 36p.

Further, in the PMOS transistor 3p of the present embodiment, a high concentration impurity region which has the same conductive type (here, N-type) as that of the channel region 35p and which also has a concentration higher than that of the channel region 35p, that is, an N-type high concentration impurity region 39p, is formed in electric connection with the channel region 35p. In the structure shown in FIG. 1, the N-type high concentration impurity region 39p is formed so as to be adjacent to the P-type high concentration impurity region 37p in a source region 30p, and is electrically connected to the source electrode 32p via the contact hole 36p.

With the structure, the channel region 35p is electrically connected to the source region 30p via the N-type high concentration impurity region 39p. Therefore, an electric potential of the channel region 35p is the same as an electric potential of the source region 30p. Accordingly, the electric potential of the channel region 35p is not varied by a change in a drain voltage, but is fixed. This makes it possible to restrain the variation in the threshold of the transistor.

As described above, in the semiconductor device of the present embodiment, an impurity region (hereinafter referred to as a same-conductive-type high-concentration impurity region) is formed in electric connection with a channel region, and has the same conductive type as that of the channel region and also has a concentration higher than that of the channel region. This fixes an electric potential of the channel region.

FIG. 1 shows a concrete example of the structure. However, the structure of the present embodiment is not limited to this, but may be other structure. For example, in the structure shown in FIG. 1, the source electrode may be connected to ground. Alternatively, in the structure shown in FIG. 1, only the same-conductive-type high concentration impurity region may be connected to ground.

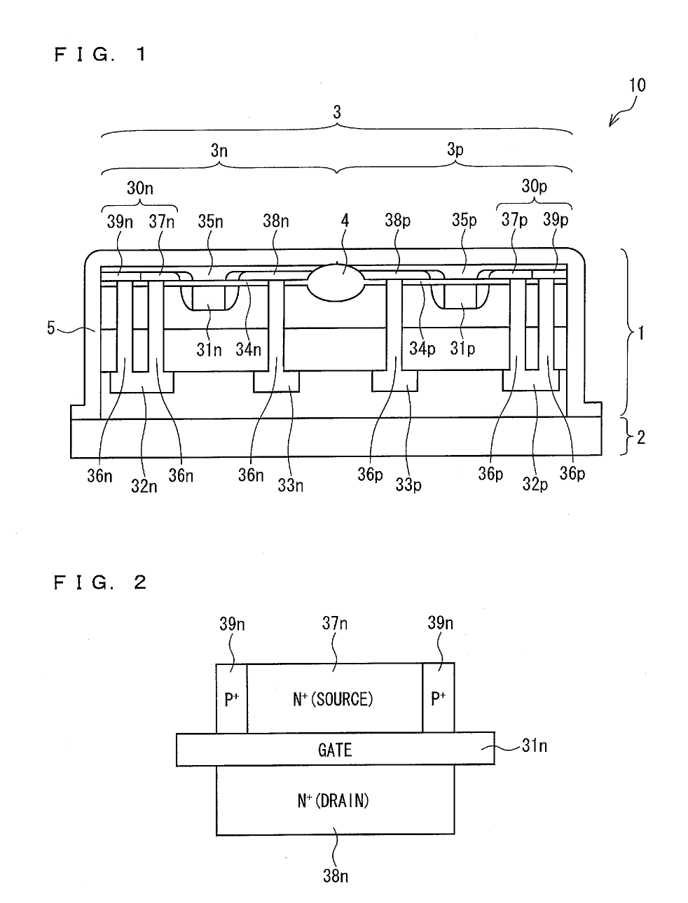

Further, the same-conductive-type high concentration impurity region may be formed so as to be adjacent to the channel region. More specifically, for example, in the NMOS transistor shown in FIG. 2, the P-type high concentration impurity region 39n may be formed in a direction perpendicular to a direction in which the gate electrode 31n, the source region 37n and the drain region 38n are aligned. This structure also provides an effect such that a length in a longitudinal direction of the channel region can be made shorter in the MOS transistor.

In this way, a position where the same-conductive-type high concentration impurity region is formed is not particularly limited, and only needs to be electrically connected to the channel region. Therefore, the position may not necessarily be in a source region. Further, the same-conductive-type high concentration impurity region may be fixed to any electric potential.

It should be noted that a film thickness of a silicon layer formed in the channel region is preferably greater than a maximum depletion layer width in the channel region. Thereby, when a gate voltage is applied and a channel is formed, there still presents, directly below the channel, a layer of the same conductive type as that of a high concentration impurity region. Therefore, an electric potential of the channel can be more reliably fixed over the whole channel region.

[Method For Producing Semiconductor Device]

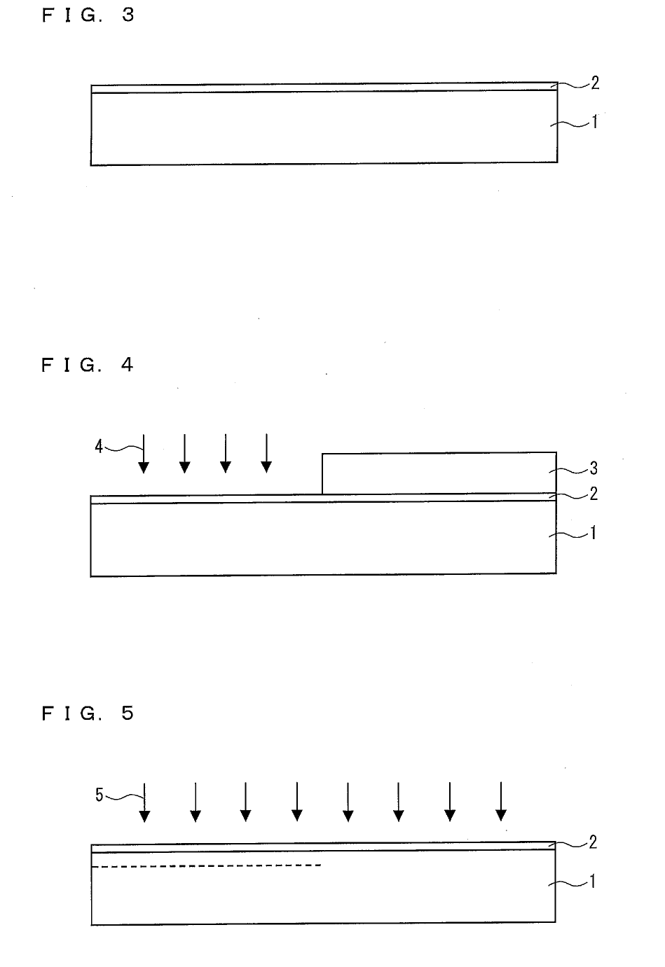

Here, the following describes a method for producing a semiconductor device 10, with reference to FIGS. 3 to 25. Note that, in the following descriptions on the manufacturing method and corresponding drawings, for convenience of descriptions, reference signs different from reference signs shown in FIG. 1 are given and corresponding reference signs of respective members shown in FIG. 1 are provided as appropriate.

A thermal oxide film 2 of, for example, approximately 30 nm is formed on a silicon substrate 1 (FIG. 3). The thermal oxide film 2 is formed for preventing contamination of a surface of the silicon substrate 1 in a subsequent step ion implantation. The thermal oxide film 2 is not necessarily essential.

A resist 3 is used as a mask, and an N-type impurity element 4 (for example, phosphorus) is injected by ion implantation into a region for forming an N-well (FIG. 4). This region is an open region of the resist 3. For example, a phosphorus element is used as the impurity element, and the impurity element is injected at an injection energy set to approximately 50 KeV to 150 KeV and at a dose amount of approximately 1E12 cm⁻² to 1E13 cm⁻². Here, when a P-type impurity is injected all over a surface of the silicon substrate 1 in the following step, the amount for injection should include an additional amount of the N-type impurity element in consideration of an equivalent amount of the N-type impurity element that will be negated by the P-type impurity.

After the resist 3 is removed, a P-type impurity element 5 (for example, boron) is injected by ion implantation all over the surface of the silicon substrate 1 (FIG. 5). For example, boron is used as the impurity element. The boron is injected at an injection energy set to approximately 10 KeV to 50 KeV and at a dose amount of approximately 1E12 cm⁻² to 1E13 cm⁻². It should be noted that, because a diffusion coefficient of phosphorus in silicon in response to a heat treatment is smaller than that of boron, the heat treatment may be performed before injection of a boron element so as to moderately diffuse the phosphorus in the silicon substrate in advance. Further, for preventing the negation of the N-type impurity by the P-type impurity in the N-well region, the P-type impurity element 5 may be injected after a resist is formed on the N-well region. Note that, in this case, there is no need to consider the negation of the N-type impurity by the P-type impurity at injection of the N-type impurity in the N-well region.

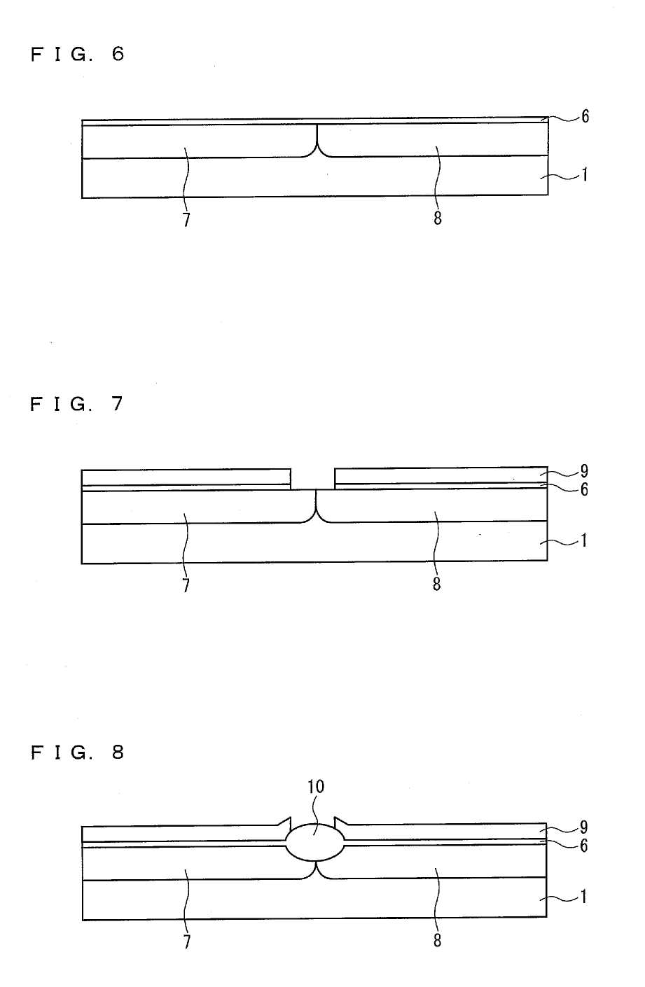

After the thermal oxide film 2 is removed, a heat treatment is performed at approximately 900° C. to 1000° C. in an oxygen atmosphere so that a thermal oxide film 6 of approximately 30 nm in thickness is formed. Further, the impurity elements injected into the N-well region and the P-well region are diffused so as to form an N-well region 7 and a P-well region 8 (FIG. 6).

After a silicon nitride film 9 of approximately 200 nm in thickness is formed by CVD (Chemical Vapor Deposition) or the like, the silicon nitride film 9 and the thermal oxide film 6 are patterned (FIG. 7).

LOCOS oxidization is performed by a heat treatment at approximately 900° C. to 1000° C. in an oxygen atmosphere so that a LOCOS oxide film 10 (LOCOS oxide film 4 in FIG. 1) of approximately 200 nm to 500 nm in thickness is formed (FIG. 8). The LOCOS oxide film 10 is for element isolation. However, the element isolation may be realized by a method other than the LOCOS oxide film, for example, by STI (Shallow Trench Isolation).

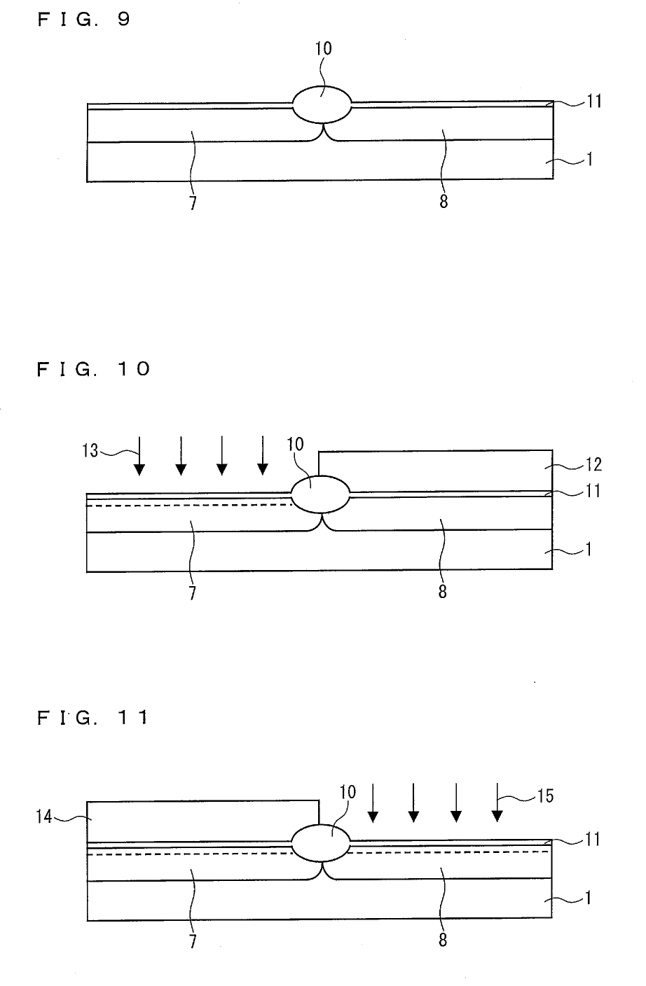

After the silicon nitride film 9 and the thermal oxide film 6 are once removed, a heat treatment is performed at approximately 1000° C. in an oxygen atmosphere so that an oxide film 11 of approximately 20 nm in thickness is formed (FIG. 9).

A resist 12 is formed so that a region for forming a PMOS transistor is open (FIG. 10). Next, an impurity element 13 is introduced into the N-well region 7 by ion implantation. The impurity element 13 is for setting a threshold voltage of the PMOS transistor. Conditions for ion implantation are, for example, such that boron as a P-type impurity is injected at 10 KeV to 50 KeV and at a dose amount of 1E12/cm² to 5E12/cm². It should be noted that the impurity to be injected may be an N-type impurity such as phosphorus and arsenic, depending on a gate electrode material and a conductive type. The N-type or P-type impurity and an amount of the N-type or P-type impurity to be injected into the channel are determined in accordance with each process condition.

A resist 14 is formed so that an NMOS transistor region is open (FIG. 11). Next, an impurity element 15 is introduced into the P-well region 8 by ion implantation. The impurity element 15 is for setting a threshold voltage of the NMOS transistor. For example, boron as a P-type impurity is injected at 10 KeV to 50 KeV and at a dose amount of 1E12/cm² to 5E12/cm². It should be noted that, as with the PMOS transistor, the impurity to be injected may be an N-type impurity such as phosphorus and arsenic, depending on a gate electrode material and a conductive type. The N-type or P-type impurity and an amount of the N-type or P-type impurity to be injected into the channel are determined in accordance with each process condition.

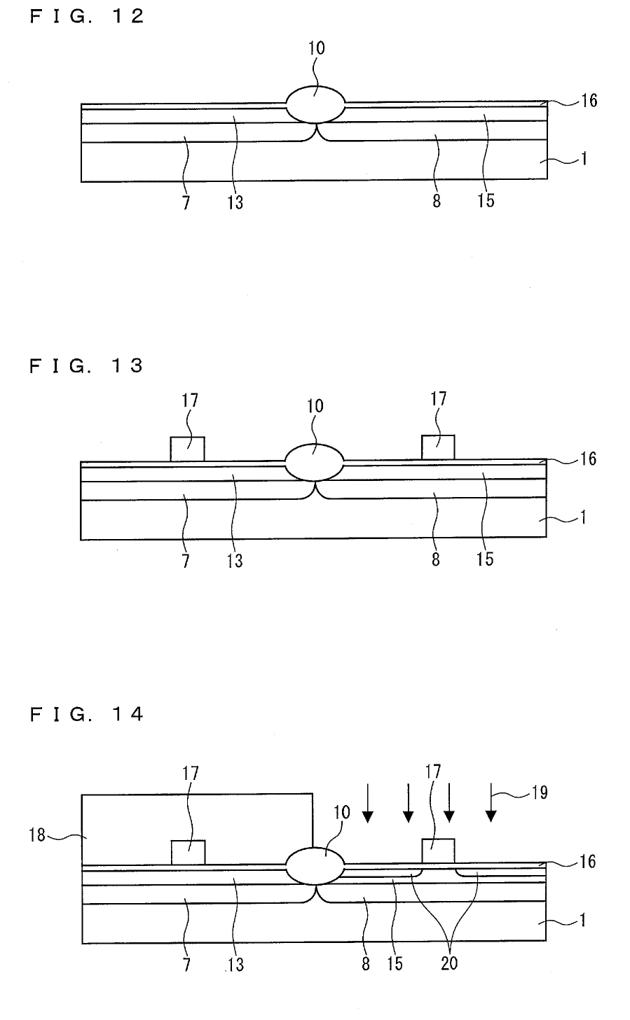

After the resist 14 and the thermal oxide film 11 are once removed, a heat treatment is performed at approximately 1000° C. in an oxygen atmosphere so that a gate oxide film 16 (gate oxide films 34n and 34p in FIG. 1) of approximately 10 nm to 20 nm in thickness is formed (FIG. 12).

Respective gate electrodes 17 (gate electrodes 31n and 31p in FIG. 1) of the NMOS transistor and the PMOS transistor are formed. After polysilicon is deposited to a thickness of approximately 300 nm by CVC or the like, an N-type impurity such as phosphorus is introduced into the gate electrodes 17 by diffusion or the like so that the polysilicon becomes N⁺ polysilicon. Then, the gate electrodes 17 are formed by patterning (FIG. 13).

A resist 18 is formed so that the region for forming the NMOS transistor is open. Then, the gate electrode 17 is used as a mask, and an N-type low concentration impurity region 20 is formed by ion implantation of an N-type impurity element 19 such as phosphorus (FIG. 14). For example, a phosphorus element is used as the N-type impurity, and conditions for the ion implantation are arranged such that, for example, the dose amount is approximately 5E12 cm⁻² to 5E13 cm⁻². It should be noted that, in FIG. 14, a semiconductor region indicated in a reference sign “15” below the gate electrode 17 shows a channel region.

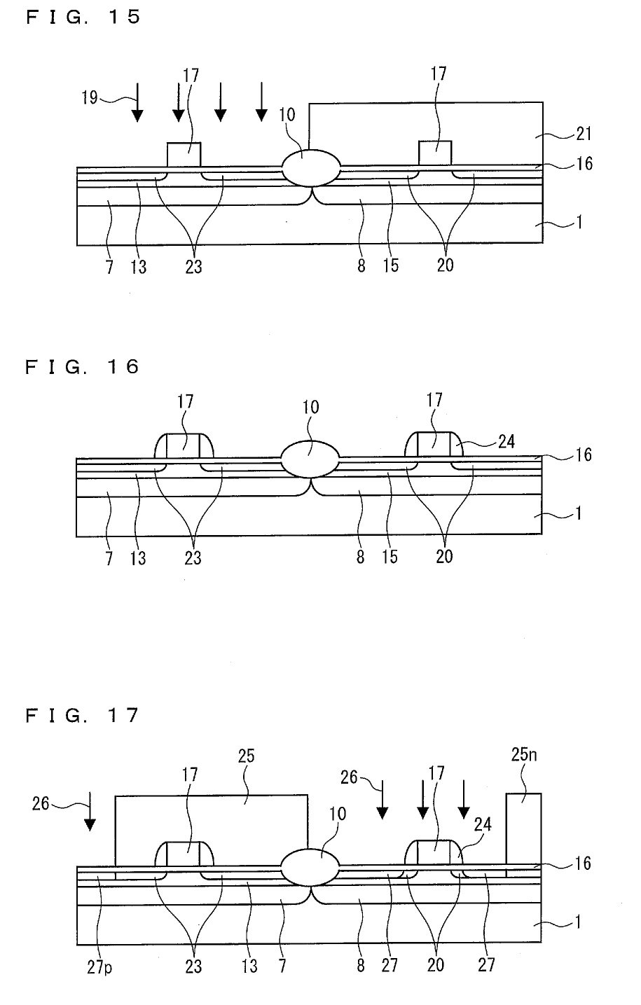

A resist 21 is formed so that the region for forming the PMOS transistor is open. Then, the gate electrode 17 is used as a mask, and a P-type low concentration impurity region is formed by ion implantation of a P-type impurity element 22 such as boron (FIG. 15). For example, a boron element is used as the P-type impurity, and conditions for the ion implantation are arranged such that, for example, the dose amount is approximately 5E12 cm⁻² to 5E13 cm⁻². It should be noted that, because a thermal diffusion coefficient of boron is large, the injection of the P-type low concentration impurity may not necessarily be performed in a case where the low concentration impurity region of the PMOS can be formed by only thermal diffusion of boron injected as a P-type high concentration impurity into the PMOS transistor in a subsequent step. It also should be noted that, in FIG. 15, a semiconductor region indicated in a reference sign number “13” below the gate electrode 17 shows a channel region.

After a SiO₂ film is formed by CVD or the like, sidewalls 24 made of SiO₂ are formed on both sidewalls of each of the gate electrodes 17 by anisotropic dry etching (FIG. 16).

A resist 25 is formed so that the region for forming the NMOS transistor is open. Then, the gate electrode 17 and the sidewalls 24 are used as masks, and N-type high concentration impurity regions 27 (N-type high concentration impurity regions 37n and 38n in FIG. 1) are formed by ion implantation of an N-type impurity element 26 such as phosphorus. At the same time, an N-type high concentration impurity region 27p (an N-type high concentration impurity region 39p in FIG. 1) is formed in a section corresponding to a source region of the PMOS transistor (FIG. 17). This makes it possible to fix an electric potential of the channel region in a case where a conductive type of the channel region of the PMOS transistor is an N-type. Further, a resist 25n is formed in a section where the P-type high concentration impurity region is to be formed, for preventing an N-type high concentration impurity from being injected into the section. This is intended to fix an electric potential in a source region of the NMOS transistor.

A resist 28 is formed so that the region for forming the PMOS transistor is open. Then, the gate electrode 17 and the sidewalls 24 are used as masks, and P-type high concentration impurity regions 30 (P-type high concentration impurity regions 37p and 38p in FIG. 1) are formed by ion implantation of a P-type impurity element 29 such as boron. At the same time, a P-type high concentration impurity region 30n (a P-type high concentration impurity region 39n in FIG. 1) is formed in a section corresponding to a source region of the NMOS transistor (FIG. 18). This makes it possible to fix an electric potential of the channel region in a case where a conductive type of the channel region of the NMOS transistor is a P-type. Further, a resist 28p is formed in a section where the N-type high concentration impurity region is formed, for preventing a P-type high concentration impurity from being injected into the section. This is intended to fix an electric potential in a source region of the PMOS transistor. Subsequently, the impurity element injected by ion implantation is activated by a heat treatment for activation. This heat treatment is performed, for example, at 900° C. for 10 minutes.

A planarizing film 31 is formed by CMP or the like, after formation of an insulating film made of SiO₂ or the like (FIG. 19).

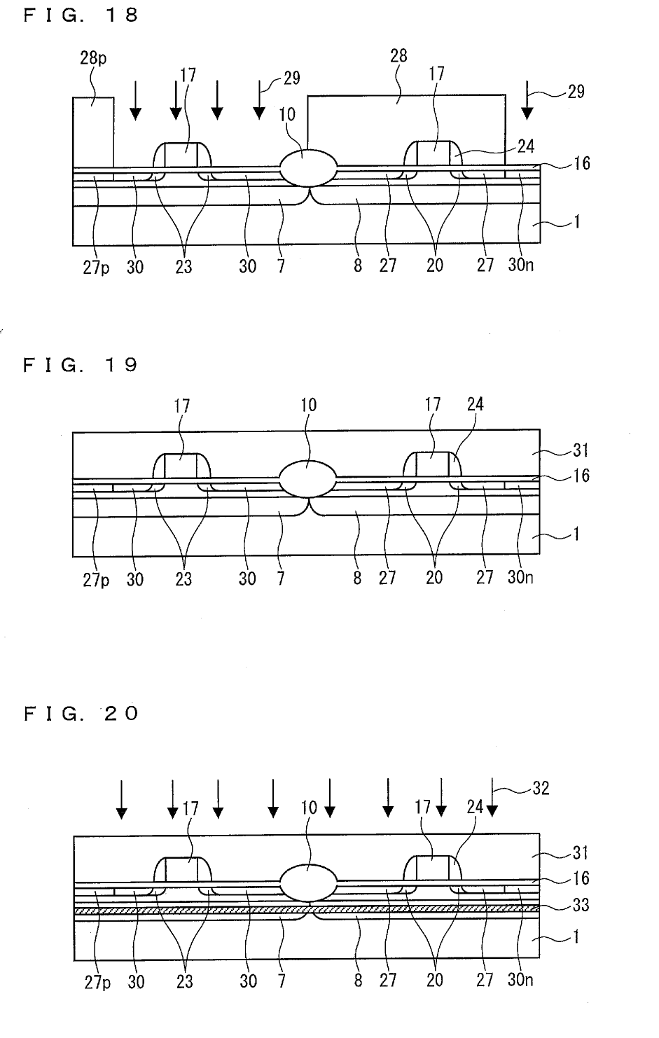

A separation layer 33 is formed by injecting, by ion implantation, a substance 32 for separation into the silicon substrate 1 (FIG. 20). This substance includes at least one of inactive elements such as hydrogen, helium and neon. Conditions for injection are arranged such that, for example, in the case of hydrogen, a dose amount is set to 2E16 cm⁻² to 1E17 cm⁻² and an injection energy is set to approximately 100 KeV to 200 KeV.

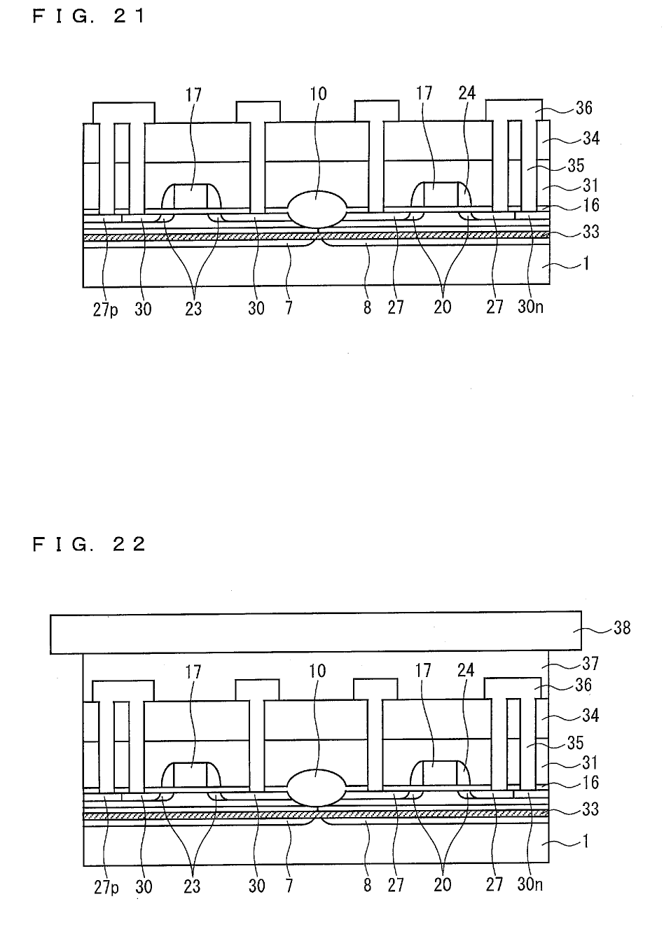

After formation of an interlayer insulating film 34, contact holes 35 are opened and metal electrodes 36 (source electrodes 32n and 32p, and drain electrodes 33n and 33p in FIG. 1) are formed (FIG. 21). It should be noted that the contact holes 35 and the metal electrodes 36 may be formed without formation of the interlayer insulating film 34, by increasing a film thickness of the planarizing film 31 that is formed before the ion implantation of the substance 32 for separation.

After formation of an insulating film 37, a surface of the insulating film 37 is made flat by CMP or the like and cleaned by SC1 or the like, and then attached to a glass substrate 38 which is also cleaned by SC1 with use of van der Waals force or a hydrogen bond (FIG. 22). Note that an SC1 cleaning solution includes ammonia, hydrogen peroxide and water, and is used for making a target surface hydrophilic.

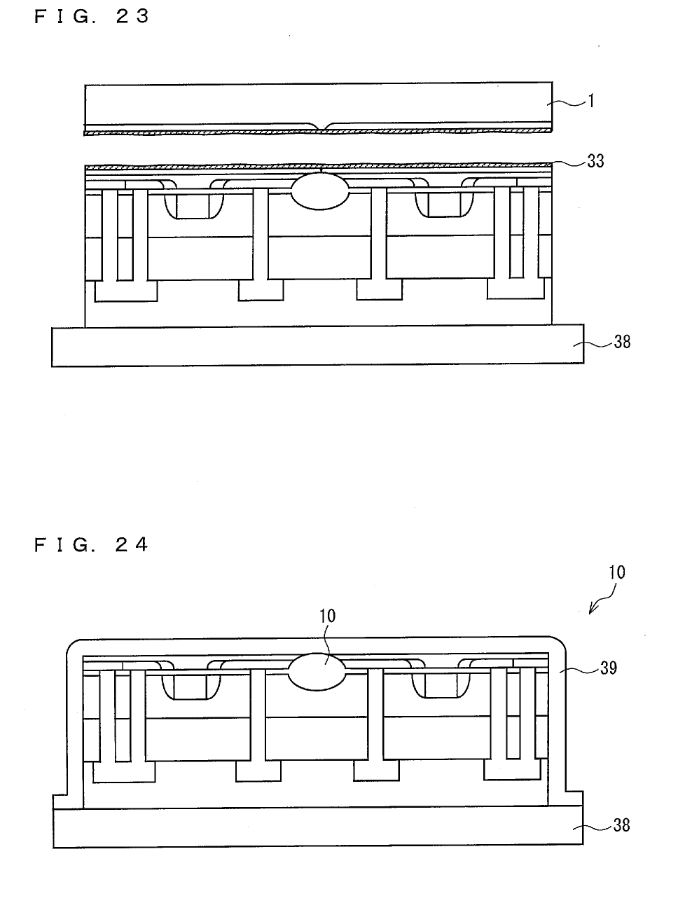

The silicon substrate 1 is separated along the separation layer 33 by performing a heat treatment at approximately 400° C. to 600° C., and the NMOS transistor and the PMOS transistor are transferred to the glass substrate 38 (FIG. 23).

After the separation layer 33 is removed by etching or the like, the semiconductor layer is etched until the LOCOS oxide film 10 is exposed. Thereby, element isolation is performed. Note that the step of etching the semiconductor layer until the LOCOS oxide film 10 is exposed is not necessarily essential. Subsequently, for protecting an exposed semiconductor surface and securing an electric insulation thereof, a protective film 39 (a protective film 5 in FIG. 1) is formed (FIG. 24).

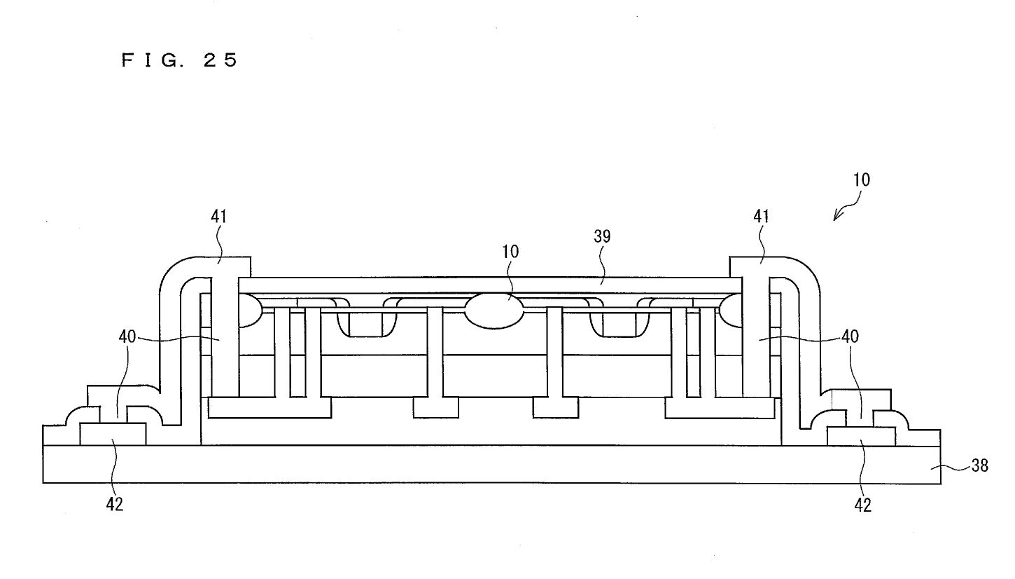

Lastly, after formation of contact holes 40, metal wirings 41 are formed. This makes it possible to achieve electrical connection with electric elements 42 such as active elements or passive elements. The electric elements 42 are fabricated in advance on the glass substrate 38 before the substrates are bonded to each other (FIG. 25).

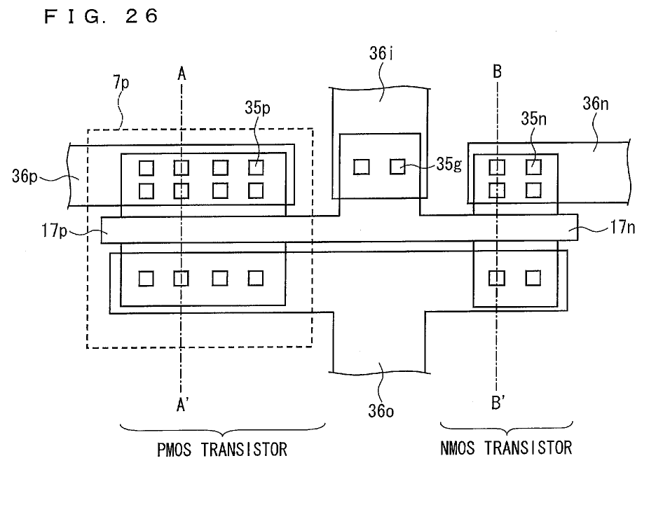

FIG. 26 shows a plain view of the semiconductor device 10 produced by the foregoing method. A cross-sectional view of the PMOS transistor in FIG. 24 corresponds to a cross-sectional view taken along line A-A′ in FIG. 26. Meanwhile, a cross-sectional view of the NMOS transistor corresponds to a cross-sectional view taken along line B-B′ in FIG. 26. The semiconductor device 10 forms a CMOS transistor, including the NMOS transistor and the PMOS transistor. More specifically, a metal wiring 36i to which an input voltage is applied is electrically connected to a gate electrode 17n of the NMOS transistor and a gate electrode 17p of the PMOS transistor via contact sections 35g. Drain electrodes of the NMOS transistor and the PMOS transistor are electrically connected to a metal wiring 36o from which an output voltage is taken out.

Note that the semiconductor device of the present invention is formed by bonding of a first substrate and a second substrate, the first substrate includes a field-effect transistor and is formed by partial separation at a separation layer made of, for example, hydrogen. In the semiconductor device of the present invention, a high concentration impurity region may be formed in electric connection with a semiconductor surface region via a semiconductor region (a region below a source region) which has the same conductive type as that of the high concentration impurity region, for fixing an electric potential of a channel region of the field-effect transistor on the first substrate. The semiconductor surface region is on a side opposite to a side where the gate electrode is formed in the channel region (particularly, a side far from the gate electrode). The high concentration impurity region has the same conductive type as that of the semiconductor surface region and also has a concentration higher than that of the semiconductor surface region.

The present invention is not limited to the description of the embodiments above, but may be altered by a skilled person within the scope of the claims. An embodiment based on a proper combination of technical means disclosed in different embodiments is encompassed in the technical scope of the present invention.

As described above, in the semiconductor device of the present invention, a high concentration impurity region is formed in electric connection with a channel region of the field-effect transistor of the first substrate so that an electric potential of the channel region is fixed. The high concentration impurity region has the same conductive type as that of the channel region and also has a concentration higher than that of the channel region.

Further, a display device of the present invention includes the semiconductor device.

This makes it possible to provide a semiconductor device whose performance can be enhanced by restraint on variation in a characteristic of a thin film transistor and a display device including the semiconductor device.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

### INDUSTRIAL APPLICABILITY

The present invention can restrain variation in a characteristic of a transistor. Thus, the present invention is suitably applicable to, particularly, an active-matrix-drive display device.

1. A semiconductor device formed by bonding a first substrate and a second substrate, the first substrate including a field-effect transistor and being formed by partial separation at a separation layer, the semiconductor device comprising:
a high concentration impurity region being formed in electric connection with a channel region of the field-effect transistor of the first substrate so that an electric potential of the channel region is fixed,
the high concentration impurity region having the same conductive type as that of the channel region and also having a concentration higher than that of the channel region.

2. The semiconductor device as set forth in claim 1, wherein:
the high concentration impurity region is formed in a source region of the field-effect transistor.

3. The semiconductor device as set forth in claim 2, wherein:
the high concentration impurity region is formed so as to be adjacent to the channel region in the source region.

4. The semiconductor device as set forth in claim 2, wherein:
the high concentration impurity region is formed so as not to be adjacent to the channel region in the source region.

5. The semiconductor device as set forth in a claim 1, wherein:
a film thickness of a silicon layer formed in the channel region in the field-effect transistor is greater than a maximum depletion layer width in the channel region.

6. The semiconductor device as set forth in claim 1:
the field-effect transistor includes at least one of an NMOS transistor and a PMOS transistor.

7. The semiconductor device as set forth in claim 1, wherein:
the first substrate includes single-crystal silicon semiconductor, or at least one selected from a group including Group IV semiconductor, Group II-VI compound semiconductor, Group III-V compound semiconductor, Group IV-IV compound semiconductor, mixed crystal semiconductor containing congeners of one of Group IV, Groups II-VI, Groups III-V, and Groups IV-IV, and an oxide semiconductor.

8. The semiconductor device as set forth in claim 1, wherein:
the high concentration impurity region and the source region are electrically connected to a source electrode.

9. The semiconductor device as set forth in claim 1, wherein:
the high concentration impurity region is connected to ground.

10. The semiconductor device as set forth in claim 1, wherein:
the second substrate is a glass substrate or a single-crystal silicon substrate.

11. A display device comprising the semiconductor device as set forth in claim 1.
